(19) United States
(12) Patent Application Publication
(10) Pub. No.: US 2025/0218944 A1
(43) Pub. Date: Jul. 3, 2025

(54) POWER RAIL LEAD FOR SEMICONDUCTOR STRUCTURES

(71) Applicant: INTERNATIONAL BUSINESS MACHINES CORPORATION, ARMONK, NY (US)

(72) Inventors: Min Gyu Sung, Latham, NY (US); Tao Li, Slingerlands, NY (US); Ruilong Xie, Niskayuna, NY (US); Nicolas Jean Loubet, GUILDERLAND, NY (US)

(21) Appl. No.: 18/396,913

(22) Filed: Dec. 27, 2023

(51) Int. Cl. H01L 23/528; H01L 29/08

(52) U.S. Cl. CPC H01L 23/5286; H01L 23/5283; H10D 62/151

(57) ABSTRACT

A semiconductor structure extends laterally with a first interconnect on one side and a second interconnect on an opposing side separated from the first interconnect by a longitudinal thickness of an insulating member that extends laterally along the first interconnect and the second interconnect. The semiconductor structure includes a first source/drain positioned in the insulating member between the first interconnect and the second interconnect, a second source/drain positioned in the insulating member adjacent to the first source/drain, and a lead electrically connected to the first source/drain and to the second interconnect, wherein a portion of the lead laps the first source/drain and the second source/drain laterally and is electrically insulated from the second source/drain.

### BACKGROUND

The present disclosure relates to semiconductor structures, and more specifically, to interconnects between layers in an integrated circuit.

Field-effect transistors (“FETs”) use an electric field effect to control current flow within a semiconductor device. Specifically, FETs may use the electric charge of their gates to affect and control the current flow through a channel. In some integrated circuits, there is a power rail that FETs can be connected to using interconnects. To prevent electrical short circuits between these interconnects, the interconnects are spaced apart from each other. However, adding space between FETs decreases the computing power density of the integrated circuit. Furthermore, reducing the size of the interconnects to increase computing power density can reduce the contact area between the power rail and the FETs. Depending on how the manufacturing tolerances of the integrated circuit stack up, some FETs end up with insufficient power connections.

### SUMMARY

According to one embodiment of the present disclosure, a semiconductor structure extends laterally with a first interconnect on one side and a second interconnect on an opposing side separated from the first interconnect by a longitudinal thickness of an insulating member that extends laterally along the first interconnect and the second interconnect. The semiconductor structure includes a first source/drain positioned in the insulating member between the first interconnect and the second interconnect, a second source/drain positioned in the insulating member adjacent to the first source/drain, and a lead electrically connected to the first source/drain and to the second interconnect, wherein a portion of the lead laps the first source/drain and the second source/drain laterally and is electrically insulated from the second source/drain.

According to another embodiment of the present disclosure, a semiconductor structure extends laterally with a first interconnect on one side and a second interconnect on an opposing side separated from the first interconnect by a longitudinal thickness of an insulating member that extends laterally along the first interconnect and the second interconnect. The semiconductor structure includes a first source/drain positioned in the insulating member between the first interconnect and the second interconnect and a lead electrically connected to the first source/drain and to the second interconnect. The lead has an L-shape that includes a contact electrically connected to the first source/drain that extends longitudinally from the first source/drain towards the second interconnect, and an extension electrically connected to the contact that extends laterally across the second interconnect.

### BRIEF DESCRIPTION OF THE DRAWINGS

FIG. 1 is a cross-section view of a semiconductor structure, in accordance with embodiments of the present disclosure.

FIG. 2 is a flowchart of a method of manufacturing the semiconductor structure of FIG. 1, in accordance with an embodiment of the present disclosure.

FIGS. 3A-3J are a series of cross-section views of stages in a manufacture of the semiconductor structure according to the method of FIG. 2, in accordance with an embodiment of the present disclosure.

FIG. 4 is a cross-section view of the semiconductor structure in a different plane from FIG. 1, in accordance with embodiments of the present disclosure.

### DETAILED DESCRIPTION

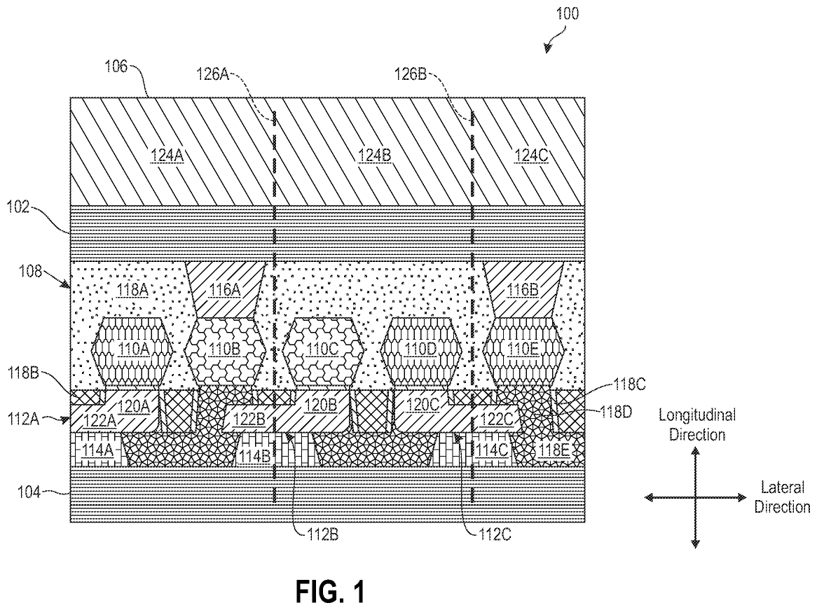

FIG. 1 is a cross-section view of semiconductor structure 100 that extends laterally (i.e., left-and-right in FIG. 1) with top interconnect 102 on one side (a.k.a., the back-end-of-line of semiconductor structure 100) and bottom interconnect 104 (a.k.a., the backside power distribution network of semiconductor structure 100) on an opposing side. Top interconnect 102 is mounted to carrier wafer 106, and top interconnect 102 and bottom interconnect 104 are separated from each other by a longitudinal thickness (i.e., top-to-bottom in FIG. 1) of insulating member 108 that extends laterally along top interconnect 102 and bottom interconnect 104.

In the illustrated embodiment, the space between top interconnect 102 and bottom interconnect 104 can be considered the device region because many electronic components reside in insulating member 108. For example, source/drain epitaxials (“S/Ds”) 110A-110E (collectively “S/Ds 110”), leads 112A-112C (collectively “leads 112”), rails 114A-114C (collectively, “rails 114”), and vias 116A-116B (collectively, “vias 116”) are selectively electrically connected together within insulating member 108 and are selectively electrically insulated from one another by insulating member 108 depending on the design of semiconductor structure 100. Insulating member 108 can be comprised of different electrically insulating structures, such as, for example, insulators 118A-118E (collectively, “insulators 118”), which can be formed at various times during the manufacture of semiconductor structure 100. Each insulator 118 of insulating member 108 can be comprised of a medium dielectric constant material (a.k.a. mid-K), such as, for example, silicon nitride (SiN), silicon dioxide (SiO2), silicon nitride carbide (SiNC), tetraethyl orthosilicate (TEOS), silicon oxycarbide (SiCOx), silicon oxycarbonitride (SiCNO), or siliconboron carbonitride (SiBCN), or a mixture of one or more of the aforementioned materials. Insulators 118 can be comprised of the same material or different materials, and a material can appear in multiple insulators 118. While one embodiment of insulating member 108 is shown in FIG. 1, other configurations and combinations of insulators are possible.

In the illustrated embodiment, S/Ds 110 are selectively electrically connected to form FETs (not shown) and can be n-type or p-type source/drains. For example, S/Ds 110B-110C can be n-type, and S/Ds 110A and 110D-110E can be p-type. For semiconductor structure 100 to function as intended, electrical connections are made within insulating member 108. These connections can be further connected to top interconnect 102 and/or bottom interconnect 104. For example, the top sides of S/Ds 110B and 110E and the bottom sides of vias 116A and 116B are in direct contact with each other, and the top sides of rails 114A-114C are in direct contact with and electrically connected to leads 112A-112C, respectively. Leads 112 have an L-shape (either standard, such as lead 112C, or reversed, such as lead 112B), so leads 112 are comprised of two regions-contacts 120A-120C (collectively “contacts 120”) and extensions 122A-122C (collectively “extensions 122”), respectively. More specifically, contacts 120 extend longitudinally from S/Ds 110, respectively, and extensions 122 extend laterally across rails 114, respectively. In some embodiments, the widths of contacts 120 are the same or smaller than the widths of S/Ds 110, and extensions 122 cover the entire top surfaces of rails 114 so the contact area between rails 114 and leads 112 is larger than the contact area between leads 112 and S/Ds 110.

In the illustrated embodiment, a portion of an extension 122 is positioned between its corresponding rail 114 and the laterally adjacent S/D 110 from the S/D 110 that the lead 112 is connected to. For example, lead 112C is electrically connected to S/D 110D, and a portion of extension 122C is positioned between the center of rail 114C and the center of S/D 110E. Moreover, extension 122C laterally laps S/D 110E, meaning that a portion of extension 122C is directly underneath a portion of S/D 110E because that portion of extension 122C has the same lateral position as that portion of S/D 110E, albeit with a different longitudinal position. However, because insulating member 108 is positioned between S/D 110E and lead 112C, lead 112C is electrically insulated from S/D 110E.

In the illustrated embodiment, rails 114 are in direct contact with and electrically connected to bottom interconnect 104. The S/Ds 110 that are not electrically connected on the bottom to rails 114 (e.g., S/Ds 110B and 110E) are instead in direct contact with and electrically connected to vias 116, respectively, on the top. Vias 116 can be considered as middle-of-line (MOL) components and are in direct contact with and electrically connected to top interconnect 102. The signal transmission components (e.g., leads 112 and vias 116) are comprised of an electrically conductive material, such as metal (e.g., titanium nitride (TiN), cobalt (Co), ruthenium (Ru), molybdenum (Mo), or tungsten (W)). The signal transmission components can be comprised of the same material or different materials, and a material can appear in multiple components.

In the illustrated embodiment, semiconductor structure 100 can be defined as comprising three cells 124A-124C (collectively “cells 124”). Cells 124 each include two S/Ds 110 (although only one is visible for cell 124C), wherein one S/D 110 is an n-type and the other is a p-type. Thereby, the borders of cells 124 are shown by longitudinally extending boundaries 126A and 126B (collectively “boundaries 126”), respectively. Rails 114 are centered and symmetric with respect to boundaries 126, so each rail 114 is located in two laterally adjacent cells 124.

The components and configuration of semiconductor structure 100 allow for electrical power to be provided to selected S/Ds 110 by bottom interconnect 104 though rails 114. Because the other S/Ds 110 are connected to top interconnect 102 through vias 116, the areas directly underneath these other S/Ds and above bottom interconnect 104 only include insulating member 108. Thereby, leads 112 can be positioned in these areas lest they remain unutilized. Allowing extensions 122 to traverse these areas means that rails 114 are laterally narrower, which increases the lateral distance between adjacent rails 114. In some embodiments, the increase in distance between rails 114 can be larger than the fin or nanosheet pitch. This prevents electrical shorts from occurring between adjacent rails 114 while still allowing S/Ds 110 to be positioned close to one another, increasing the computing power of semiconducting structure 100. Furthermore, extensions 122 allow for greater contact between leads 112 and rails 114 since the entire tops of rails 114 are available for contact, as opposed to only the areas that are lapped by contacts 120. This can be helpful, for example, because it makes semiconductor structure 100 less susceptible to having an insufficient connection between leads 112 and rails 114 due to manufacturing tolerances.

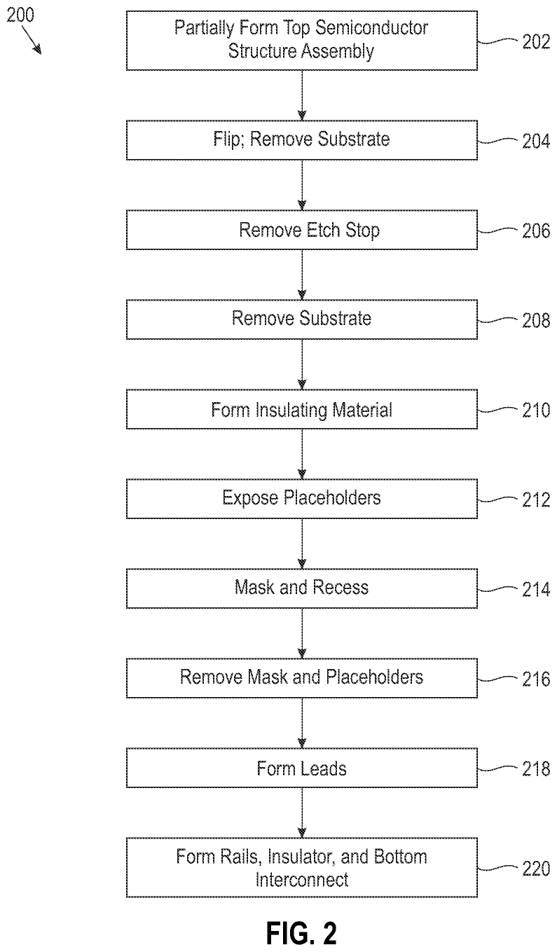

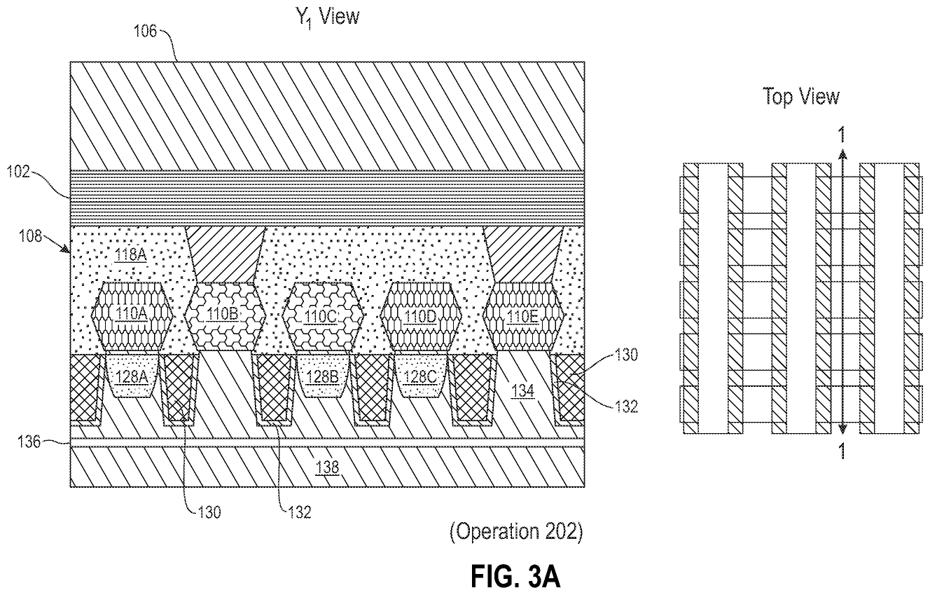

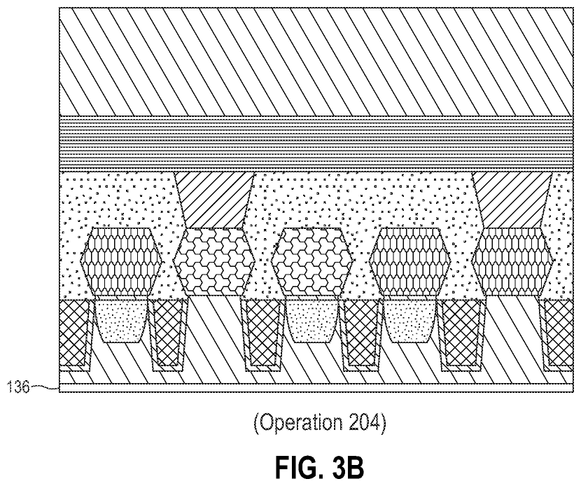

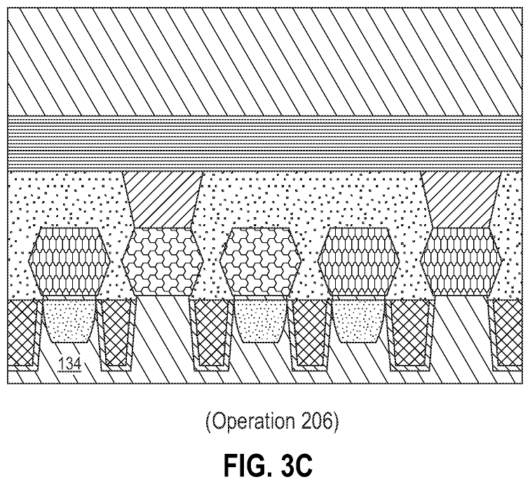

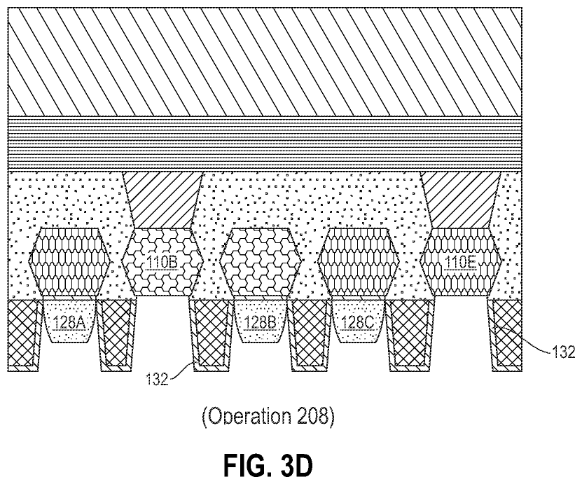

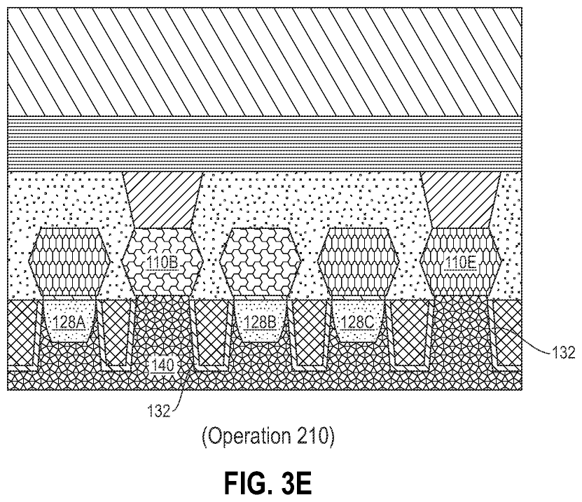

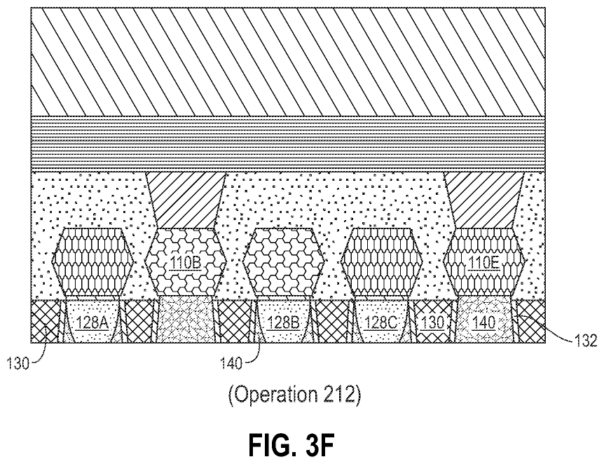

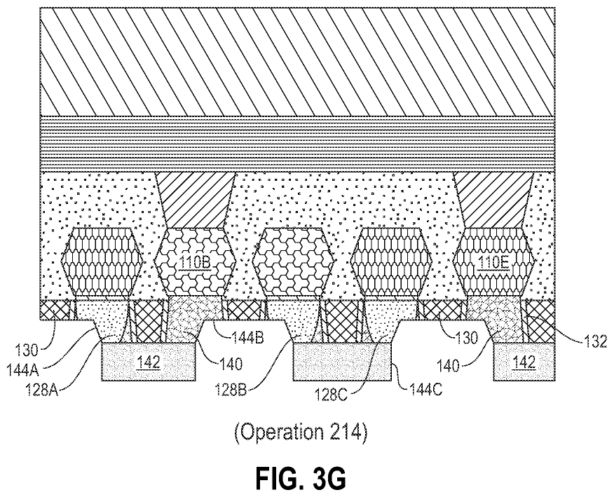

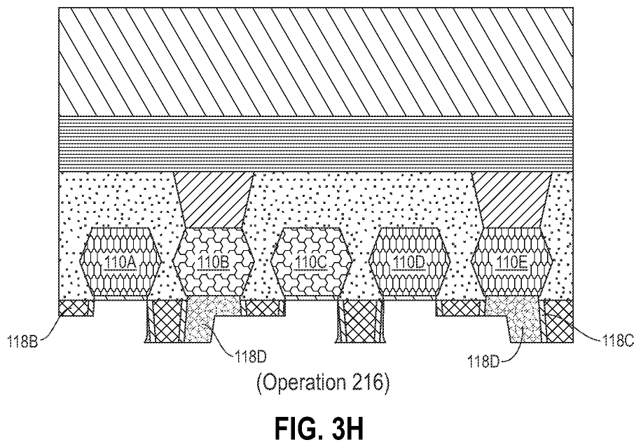

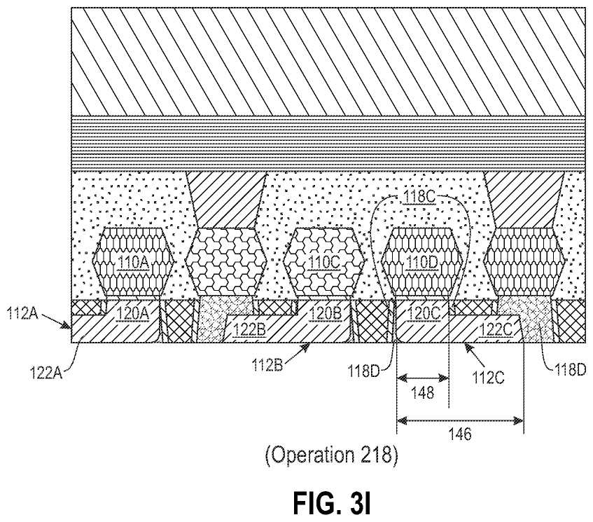

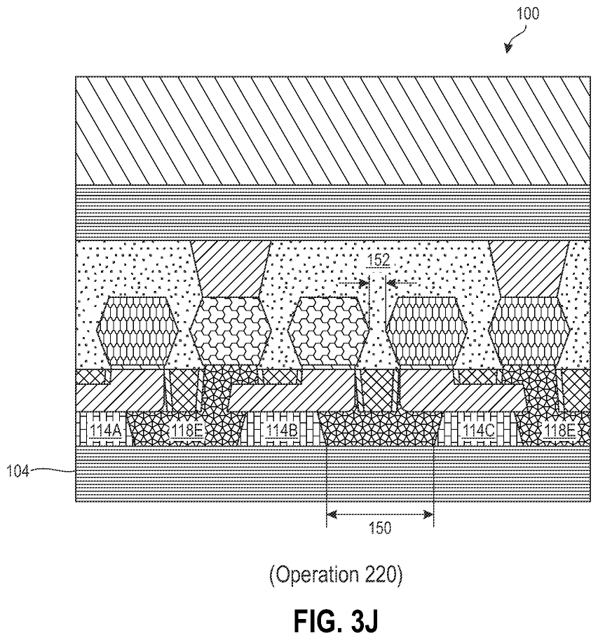

FIG. 2 is a flowchart of method 200 of manufacturing semiconductor structure 100. FIGS. 3A-3J are a series of cross-section views of stages in a manufacture of semiconductor structure 100 according to method 200. The results of each operation in method 200 are illustrated in one of FIGS. 3A-3J, so FIGS. 2 and 3A-3J will be discussed in conjunction with one another. In addition, during this discussion, references may be made to features of semiconductor structure 100 (shown in FIG. 1), however, some features may be omitted for the sake of simplicity. FIG. 3A includes a top view and a Y₁ view, and the orientation and location of the Y₁ view is indicated by line 1-1 in the top view. This Y₁ view orientation and location provides a frame of reference for FIG. 1 and FIGS. 3B-3J as well.

In the illustrated embodiment, method 200 begins at operation 202 wherein a top semiconductor structure assembly is partially formed. In particular, as shown in FIG. 3A, top interconnect 102; carrier wafer 106; a portion of insulating member 108 (i.e., insulator 118A), S/Ds 110, vias 116, placeholders 128A-128C (collectively “placeholders 128”), insulating material 130, insulating material 132, substrate 134, etch stop 136, and substrate 138 have been formed. Placeholders 128 only exist underneath S/Ds 110A, 110C, and 110D since these S/Ds 110 will eventually be connected to leads 112. In some embodiments, placeholders 128 are epitaxial components comprised of a different silicon material (e.g., one with a different germanium content) from that of carrier wafer 106, substrate 134, and/or substrate 138. In addition, the recesses for placeholders 128 were dug in the same operation as the recesses for S/Ds 110A, 110C, and 110D, so placeholders 128 are self-aligned with their respective S/Ds 110. As will be seen later in method 200, placeholders 128 form the general sizes and shapes of contacts 120, respectively.

In the illustrated embodiment, at operation 204, the partially-formed assembly that has been made so far is flipped to provide access to its bottom side and the substrate is removed. Notably, the orientation is not changed from FIG. 3A to FIG. 3B for visual continuity. As shown in FIG. 3B, substrate 138 has been removed to expose etch stop 136. At operation 206, the etch stop is removed. In particular, as shown in FIG. 3C, etch stop 136 has been removed to expose substrate 134. At operation 208, the substrate is removed. More specifically, as shown in FIG. 3D, substrate 134 has been removed to expose S/Ds 110B and 110E, placeholders 128, and insulating material 132. At operation 210, insulating material is formed. Accordingly, as shown in FIG. 3E, insulating material 140 is formed on S/Ds 110B and 110E, placeholders 128, and insulating material 132. At operation 212, placeholders are exposed. In particular, as shown in FIG. 3F, some of insulating material 140 is removed to expose placeholders 128, insulating material 130, and insulating material 132, but insulating material 140 remains on the bottoms of S/Ds 110B and 110E and the lateral sides of placeholders 128. At operation 214, the structure is masked and recessed. More specifically, as shown in FIG. 3G, mask 142 is selectively applied to the assembly thus far, and recesses 144A-144C (collectively “recesses 144”) are formed by removing portions of placeholders 128, insulating material 130, insulating material 132, and insulating material 140. As will be seen later in method 200, recesses 144 form the general sizes and shapes of extensions 122, respectively. At operation 216, the mask and placeholders arc removed. In particular, as shown in FIG. 3H, mask 142 and placeholders 128 are removed to expose S/Ds 110A, 110C, and 110D. Also at operation 216, insulators 118B, 118C, and 118D arc finalized, and insulators 118D remain so that S/Ds 110B and 110E are not exposed.

In the illustrated embodiment, at operation 218, leads are formed. Accordingly, as shown in FIG. 3I, leads 112 are formed on S/Ds 110A, 110C, and 110D, respectively. In some embodiments, the lateral widths 146 of extensions 122 are twice as wide as the lateral widths 148 of contacts 120. In addition, the lateral sides of contacts 120 are in direct contact with insulator 118C, whereas the lateral sides of extensions 122 are in direct contact with insulator 118D. At operation 220, rails, insulator, and bottom interconnect are formed. In particular, as shown in FIG. 3J, rails 114, insulator 118E, and bottom interconnect 104 are formed on insulators 118B, 118C, and 188D and contacts 120, respectively. In some embodiments, the lateral distance between two adjacent rails 114 (e.g., as indicated by width 150) is two times greater than the lateral distance between two adjacent S/Ds 110 (e.g., as indicated by width 152).

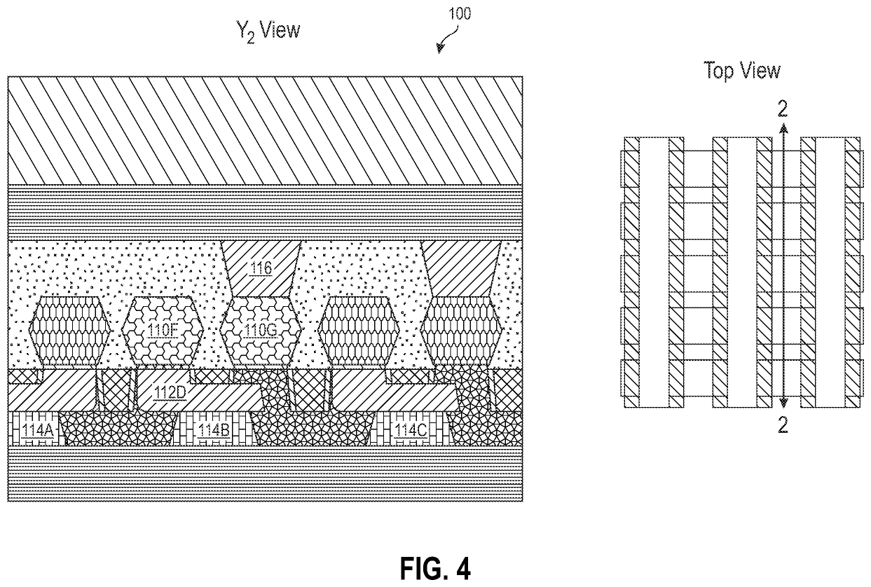

FIG. 4 includes a top view and a cross-section Y₂ view of semiconductor structure 100, and the orientation and location of the Y₂ view is indicated by line 2-2 in the top view. The location of the Y₂ view is set back from that of the Y₁ view (shown in FIG. 3A) in a direction that is orthogonal to the lateral direction in both the Y₁ and Y₂ views. In other words, rails 114 extend into and out of the pages in the Y₁ and Y₂ views, and the difference between the Y₁ and Y₂ views is the locations along rails 114.

In the illustrated embodiment, rails 114 lap two adjacent S/Ds 110 laterally. For example, rail 114B laps S/Ds 110F and 110G laterally, as well as lapping S/Ds 110B and 110C (shown in FIG. 1) laterally. Thereby, rails 114 can supply electrical power to either of the adjacent lapping S/Ds 110, depending on the configuration of leads 112. For example, rail 114B supplies power to S/D 110C (on the right side of rail 114B) in plane Y₁ (shown in FIG. 3) through lead 112B, and rail 114B supplies power to S/D 110B (on the left side of rail 114B) in plane Y₂ through lead 112D. However, in some embodiments, both adjacent S/Ds 110 are connected to the same rail 114, although in such embodiments, neither of the adjacent S/Ds 110 would be connected to a via 116.

Various embodiments of the present disclosure are described herein with reference to the related drawings. Alternative embodiments can be devised without departing from the scope of the present disclosure. It is noted that various connections and positional relationships (e.g., over, below, adjacent, etc.) are set forth between elements in the following description and in the drawings. These connections and/or positional relationships, unless specified otherwise, can be direct or indirect, and the present disclosure is not intended to be limiting in this respect. Accordingly, a coupling of entities can refer to either a direct or an indirect coupling, and a positional relationship between entities can be a direct or indirect positional relationship. As an example of an indirect positional relationship, references in the present description to forming layer “A” over layer “B” include situations in which one or more intermediate layers (e.g., layers “C” and “D”) are between layer “A” and layer “B” as long as the relevant characteristics and functionalities of layer “A” and layer “B” are not substantially changed by the intermediate layer(s).

The following definitions and abbreviations are to be used for the interpretation of the claims and the specification. As used herein, the terms “comprises,” “comprising,” “includes,” “including,” “has,” “having,” “contains” or “containing,” or any other variation thereof, are intended to cover a non-exclusive inclusion. For example, a composition, a mixture, process, method, article, or apparatus that comprises a list of elements is not necessarily limited to only those elements but can include other elements not expressly listed or inherent to such composition, mixture, process, method, article, or apparatus. In addition, any numerical ranges included herein are inclusive of their boundaries unless explicitly stated otherwise.

For purposes of the description hereinafter, the terms “upper,” “lower,” “right,” “left,” “vertical,” “horizontal,” “top,” “bottom,” and derivatives thereof shall relate to the described structures and methods, as oriented in the drawing figures. The terms “overlying,” “atop,” “on top,” “positioned on” or “positioned atop” mean that a first element, such as a first structure, is present on a second element, such as a second structure, wherein intervening elements such as an interface structure can be present between the first element and the second element. The term “direct contact” means that a first element, such as a first structure, and a second element, such as a second structure, are connected without any intermediary conducting, insulating or semiconductor layers at the interface of the two elements. It should be noted, the term “selective to,” such as, for example, “a first element selective to a second element,” means that a first element can be etched, and the second element can act as an etch stop.

For the sake of brevity, conventional techniques related to semiconductor device and integrated circuit (IC) fabrication may or may not be described in detail herein. Moreover, the various tasks and process steps described herein can be incorporated into a more comprehensive procedure or process having additional steps or functionality not described in detail herein. In particular, various steps in the manufacture of semiconductor devices and semiconductor-based ICs are well known and so, in the interest of brevity, many conventional steps will only be mentioned briefly herein or will be omitted entirely without providing the well-known process details.

In general, the various processes used to form a micro-chip that will be packaged into an IC fall into four general categories, namely, film deposition, removal/etching, semiconductor doping and patterning/lithography.

Deposition can be any process that grows, coats, or otherwise transfers a material onto the wafer. Available technologies include physical vapor deposition (PVD), chemical vapor deposition (CVD), electrochemical deposition (ECD), molecular beam epitaxy (MBE) and more recently, atomic layer deposition (ALD) among others. Another deposition technology is plasma enhanced chemical vapor deposition (PECVD), which is a process which uses the energy within the plasma to induce reactions at the wafer surface that would otherwise require higher temperatures associated with conventional CVD. Energetic ion bombardment during PECVD deposition can also improve the film's electrical and mechanical properties.

Removal/etching can be any process that removes material from the wafer. Examples include etch processes (either wet or dry), chemical mechanical planarization (CMP), and the like. One example of a removal process is ion beam etching (IBE). In general, IBE (or milling) refers to a dry plasma etch method which utilizes a remote broad beam ion/plasma source to remove substrate material by physical inert gas and/or chemical reactive gas means. Like other dry plasma etch techniques, IBE has benefits such as etch rate, anisotropy, selectivity, uniformity, aspect ratio, and minimization of substrate damage. Another example of a dry removal process is reactive ion etching (RIE). In general, RIE uses chemically reactive plasma to remove material deposited on wafers. With RIE the plasma is generated under low pressure (vacuum) by an electromagnetic field. High-energy ions from the RIE plasma attack the wafer surface and react with it to remove material.

Semiconductor doping can be the modification of electrical properties by doping, for example, transistor sources and drains, generally by diffusion and/or by ion implantation. These doping processes are followed by furnace annealing or by rapid thermal annealing (“RTA”). Annealing serves to activate the implanted dopants. Films of both conductors (e.g., poly-silicon, aluminum, copper, etc.) and insulators (e.g., various forms of silicon dioxide, silicon nitride, etc.) are used to connect and isolate transistors and their components. Selective doping of various regions of the semiconductor substrate allows the conductivity of the substrate to be changed with the application of voltage. By creating structures of these various components, millions of transistors can be built and wired together to form the complex circuitry of a modern microelectronic device.

Semiconductor lithography can be the formation of three-dimensional relief images or patterns on the semiconductor substrate for subsequent transfer of the pattern to the substrate. In semiconductor lithography, the patterns are formed by a light sensitive polymer called a photoresist. To build the complex structures that make up a transistor and the many wires that connect the millions of transistors of a circuit, lithography and etch pattern transfer steps are repeated multiple times. Each pattern being printed on the wafer is aligned to the previously formed patterns and gradually the conductors, insulators and selectively doped regions are built up to form the final device.

The descriptions of the various embodiments of the present invention have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

What is claimed is:

1. A semiconductor structure that extends laterally with a first interconnect on one side and a second interconnect on an opposing side separated from the first interconnect by a longitudinal thickness of an insulating member that extends laterally along the first interconnect and the second interconnect, the semiconductor structure comprising:
a first source/drain (S/D) positioned in the insulating member between the first interconnect and the second interconnect;
a second S/D positioned in the insulating member adjacent to the first S/D; and
a lead electrically connected to the first S/D and to the second interconnect, wherein a portion of the lead laps the first S/D and the second S/D laterally and is electrically insulated from the second S/D.

2. The semiconductor structure of claim 1, further comprising a first rail that is electrically connected to the first S/D and to the second interconnect.

3. The semiconductor structure of claim 2, wherein the first rail is configured to supply electrical power to the first S/D.

4. The semiconductor structure of claim 2, further comprising a middle-of-line via electrically connected to the second S/D and to the first interconnect.

5. The semiconductor structure of claim 2, further comprising a second rail that is electrically insulated from the first rail, wherein a first lateral distance between the first rail and the second rail is greater than a second lateral distance between the first S/D and the second S/D.

6. The semiconductor structure of claim 2, wherein the first rail laps the first S/D and the second S/D laterally.

7. The semiconductor structure of claim 5, further comprising a third S/D and a fourth S/D, wherein:
the first S/D and the second S/D are spaced apart in a first direction;
the third S/D spaced apart from the first S/D in a second direction that is orthogonal to the first direction;
the fourth S/D spaced apart from the second S/D in the second direction; and
the fourth S/D is electrically connected to the first rail;
wherein the first rail laps the third S/D and the fourth S/D laterally.

8. The semiconductor structure of claim 2, wherein the first rail is centered and symmetric with respect to a cell border.

9. The semiconductor structure of claim 1, further comprising a via electrically connected to the second S/D and to the first interconnect, wherein the via is positioned on an opposite side of the second S/D from the lead.

10. The semiconductor structure of claim 1, wherein the lead has an L-shape.

11. A semiconductor structure that extends laterally with a first interconnect on one side and a second interconnect on an opposing side separated from the first interconnect by a longitudinal thickness of an insulating member that extends laterally along the first interconnect and the second interconnect, the semiconductor structure comprising:
a first source/drain (S/D) positioned in the insulating member between the first interconnect and the second interconnect;
a lead electrically connected to the first S/D and to the second interconnect, wherein the lead has an L-shape that comprises:
a contact electrically connected to the first S/D that extends longitudinally from the first S/D towards the second interconnect; and
an extension electrically connected to the contact that extends laterally across the second interconnect.

12. The semiconductor structure of claim 11, wherein:
the semiconductor structure further comprises a second S/D positioned in the insulating member adjacent to the first S/D; and
the extension laps the second S/D laterally and is electrically insulated from the second S/D.

13. The semiconductor structure of claim 11, wherein a width of the extension is at least twice a width of the contact.

14. The semiconductor structure of claim 11, further comprising a via electrically connected to the second S/D and to the first interconnect, wherein the contact is positioned on an opposite side of the second S/D from the lead.

15. The semiconductor structure of claim 11, wherein:
the insulating member comprises a plurality of insulators;
lateral sides of the contact are in direct contact with a first insulator of the plurality of insulators.

16. The semiconductor structure of claim 15, wherein lateral sides of the extension are in direct contact with a second insulator of the plurality of insulators that is different from the first insulator.

17. The semiconductor structure of claim 11, further comprising a first rail that is electrically connected to the first S/D and to the second interconnect, wherein the first rail laps the first S/D and the second S/D laterally.

18. The semiconductor structure of claim 11, wherein the first rail is centered and symmetric with respect to a cell border.

19. The semiconductor structure of claim 17, further comprising a third S/D and a fourth S/D, wherein:
the first S/D and the second S/D are spaced apart in a first direction;
the third S/D spaced apart from the first S/D in a second direction that is orthogonal to the first direction;
the fourth S/D spaced apart from the second S/D in the second direction; and
the fourth S/D is electrically connected to the first rail;
wherein the first rail laps the third S/D and the fourth S/D laterally.

20. The semiconductor structure of claim 11, wherein the lead has an L-shape.
